(19) United States
(12) Patent Application Publication
(10) Pub. No.: US 2018/0033609 A1
(43) Pub. Date: Feb. 1, 2018

(54) REMOVAL OF NON-CLEAVED/NON-TRANSFERRED MATERIAL FROM DONOR SUBSTRATE

(71) Applicant: QMAT, Inc., Santa Clara, CA (US)

(72) Inventor: Francois J. HENLEY, Saratoga, CA (US)

(21) Appl. No.: 15/643,384

(22) Filed: Jul. 6, 2017

Related U.S. Application Data
(60) Provisional application No. 62/367,911, filed on Jul. 28, 2016.

(51) Int. Cl. H01L 21/02; H01L 21/762; H01L 21/683; H01L 21/66

(52) U.S. Cl. CPC H01L 21/02032; H01L 22/24; H01L 21/76254; H01L 21/6835; H01L 21/0254; H01L 21/02546; H01L 21/02617; H01L 2221/68368

(57) ABSTRACT

Embodiments relate to reclaiming a donor substrate that has previously supplied a thin film of material in a layer transfer process. Certain embodiments selectively perform annular grinding upon edge regions only of the donor substrate. This serves to remove residual material at the edge regions, with grind damage not impacting subsequent transfer of material from central regions of the donor substrate. Some embodiments accomplish reclamation by applying energy to the donor substrate after cleaving has occurred. The energy is calculated to interact with a cleave region (e.g., resulting from ion implantation) underlying the residual material, thereby allowing separation of that residual material at the cleave region. This reclamation approach can remove residual material in donor substrate central regions (e.g., resulting from a void), without requiring invasive grinding and post-grinding processing to remove grind damage. Embodiments may apply energy in the form of a laser beam absorbed at the cleave region.

### CROSS-REFERENCE TO RELATED APPLICATION

The instant nonprovisional patent application claims priority to U.S. Provisional Patent Appl. 62/367,911 filed Jul. 28, 2016 and incorporated by reference in its entirety herein for all purposes.

### BACKGROUND

Conventional techniques for manufacturing electronic devices, may involve the formation and manipulation of thin layers of materials. One example of such manipulation is the transfer of a thin layer of material from a first (donor) substrate to a second (target) substrate. This may be accomplished by placing a face of the donor substrate against a face of the target substrate, and then cleaving the thin layer of material along a sub-surface cleave plane formed in the donor substrate.

The donor substrate may comprise valuable, high quality crystalline material that is expensive to produce. Thus, following such a layer transfer process, the donor substrate may be sought to be reclaimed for subsequent use in further layer transfer efforts. Accordingly, there is a need in the art for methods and apparatuses of processing a donor substrate to allow for its reclamation for subsequent layer transfer.

### SUMMARY

Embodiments relate to reclaiming a donor substrate that has previously supplied a thin film of material in a layer transfer process. Certain embodiments selectively perform annular grinding upon edge regions only of the donor substrate. This serves to remove residual material at the edge regions, with grind damage not impacting subsequent transfer of material from central regions of the donor substrate. Some embodiments accomplish reclamation by applying energy to the donor substrate after cleaving has occurred. The energy is calculated to interact with a cleave region (e.g., resulting from ion implantation) underlying the residual material, thereby allowing separation of that residual material at the cleave region. This reclamation approach can remove residual material in donor substrate central regions (e.g., resulting from a void), without requiring invasive grinding and post-grinding processing to remove grind damage. Embodiments may apply energy in the form of a laser beam absorbed at the cleave region.

### BRIEF DESCRIPTION OF THE DRAWINGS

FIG. 1 shows a simplified view of a fabrication process involving the reclamation of a GaN substrate.

FIG. 1A is a simplified view showing the Ga face and N face of a GaN substrate.

FIGS. 2A-2G show simplified views a GaN substrate undergoing reclamation according to one embodiment.

FIGS. 3A-3G show simplified views of a GaN substrate undergoing reclamation according to another embodiment.

FIG. 4 illustrates a simplified flow diagram of a reclamation process according to an embodiment.

### DETAILED DESCRIPTION

Semiconducting materials find many uses, for example in the formation of logic devices, solar cells, and increasingly, illumination. One type of semiconductor device that can be used for illumination is the high-brightness light emitting diode (HB-LED). In contrast with traditional incandescent or even fluorescent lighting technology, HB-LED's offer significant advantages in terms of reduced power consumption and reliability.

An optoelectronic device such as a HB-LED may rely upon materials exhibiting semiconductor properties, including but not limited to type III/V materials such as gallium nitride (GaN) or Aluminum Nitride (AlN) that is available in various degrees of crystalline order. However, these materials are often difficult to manufacture.

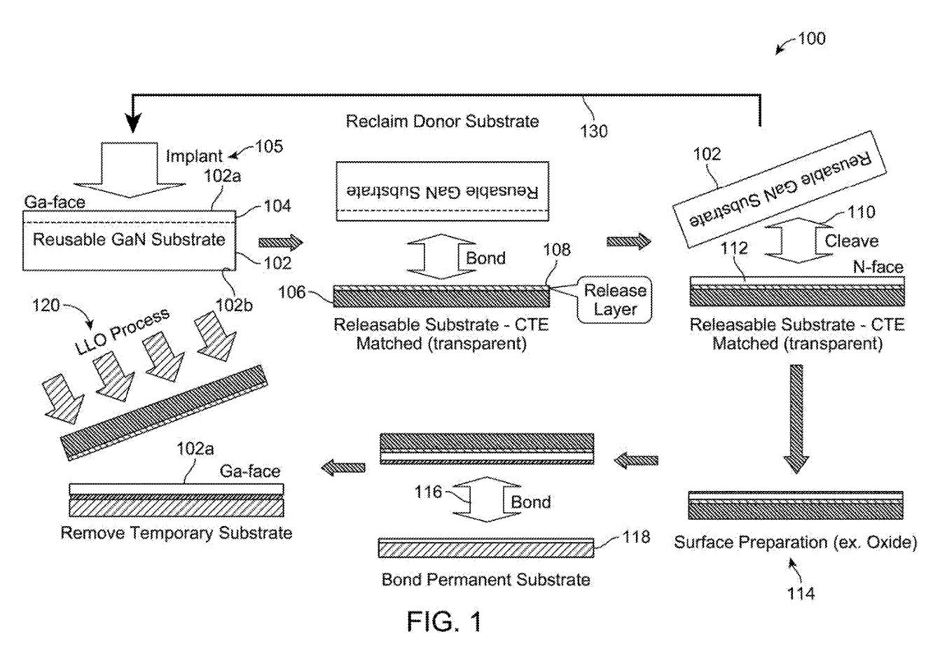

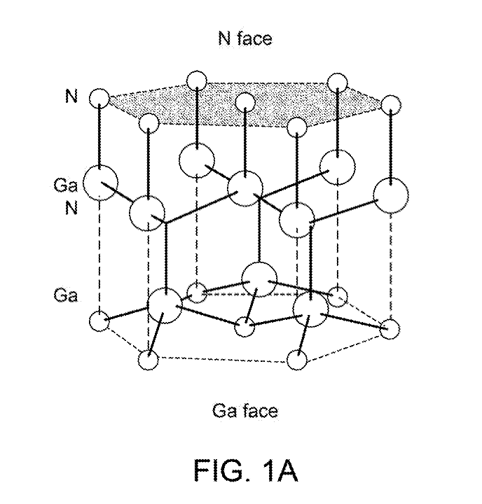

Examples of possible approaches for fabricating a template suitable for high quality GaN growth, are described in U.S. provisional patent application No. 62/181,947 filed Jun. 19, 2015 (“the '947 provisional application”), and also the U.S. nonprovisional patent application Ser. No. 15/186,184 filed Jun. 17, 2016, both of which are incorporated by reference in its entirety herein for all purposes. FIG. 1 shows a simplified view of one fabrication process 100 to form a permanent substrate offering a template for the subsequent growth of high quality GaN for optoelectronic applications.

In this example, a donor substrate 102 comprises high-quality GaN material. A cleave region 104 is located at a sub-surface region of the donor substrate. This cleave region may be formed, for example, by the energetic implantation 105 of particles such as hydrogen ions, into one face of the GaN donor substrate.

Here, it is noted that the crystalline structure of the GaN donor substrate, results in it having two distinct faces: a Ga face 102a, and an N face 102b. FIG. 1A is a simplified view illustrating the internal structure of a GaN substrate, showing the Ga face and the N face.

In a next step of the process of FIG. 1, the implanted Ga face of the GaN substrate is bonded to a releasable substrate 106 bearing a release layer 108. The material of the releasable substrate may be selected such that its Coefficient of Thermal Expansion (CTE) substantially matches that of the GaN. As discussed later in detail below, the material of the releasable substrate may also be selected to be transparent to incident laser light as part of a Laser Lift Off (LLO) process. In connection with these desired properties, a releasable substrate comprising glass may be used.

The release layer may comprise a variety of materials capable of later separation under controlled conditions. As described in the '947 provisional application, candidate releasable materials can include those undergoing conversion from the solid phase to the liquid phase upon exposure to thermal energy within a selected range. Examples can include soldering systems, and systems for Thermal Lift Off (TLO).

In certain embodiments the release system may comprise silicon oxide. In particular embodiments this bond-and-release system can be formed by exposing the workpieces to oxidizing conditions. In some embodiments this bond-and-release system may be formed by the addition of oxide, e.g., as spin-on-glass (SOG), or other spin on material (e.g., XR-1541 hydrogen silsesquioxane electron beam spin-on resist available from Dow Corning), and/or SiO2 formed by Plasma Enhanced Chemical Vapor Deposition (PECVD) techniques.

In a next step of the process of FIG. 1, energy is applied to cleave 110 the GaN substrate along the cleave region, resulting in a separated layer of GaN material 112 remaining attached to the release layer and the releasable substrate. Examples of such cleaving processes are disclosed in U.S. Pat. No. 6,013,563, incorporated by reference in its entirety herein.

Following cleaving of the GaN, FIG. 1 shows a number of subsequent steps that are performed in order to create the template for high-quality GaN growth. These steps include surface preparation 114 of the separated GaN layer (e.g., the formation of an oxide), bonding 116 the separated GaN layer to a permanent substrate 118, and finally the removal of the releasable substrate utilizing the release layer (e.g., utilizing a LLO process 120), to result in the N face of the separated GaN layer being bonded to the permanent substrate.

The Ga face is exposed and available for growth of additional high quality GaN material under desired conditions. Additional GaN may be formed by Metallo-Organic Chemical Vapor Deposition (MO-CVD), for example. That additional thickness of GaN material (with or without the accompanying substrate and/or dielectric material) may ultimately be incorporated into a larger optoelectronic device structure (such as a HB-LED).

Returning to the third (cleaving) step shown in FIG. 1, separation of the GaN film results in the valuable GaN donor substrate being available for re-use in order to create additional template structures for high quality GaN growth. This can be accomplished by performing additional implantation, and then bonding to a releasable substrate.

However, before such re-use can properly take place, the GaN donor substrate may need to first be reclaimed so that it is suitable for the intended processing. In particular, the Ga face of the donor substrate may exhibit properties such as surface roughness, defects, and/or non-planarity resulting from the previous cleaving step, that render it unsuitable for immediate implantation and bonding.

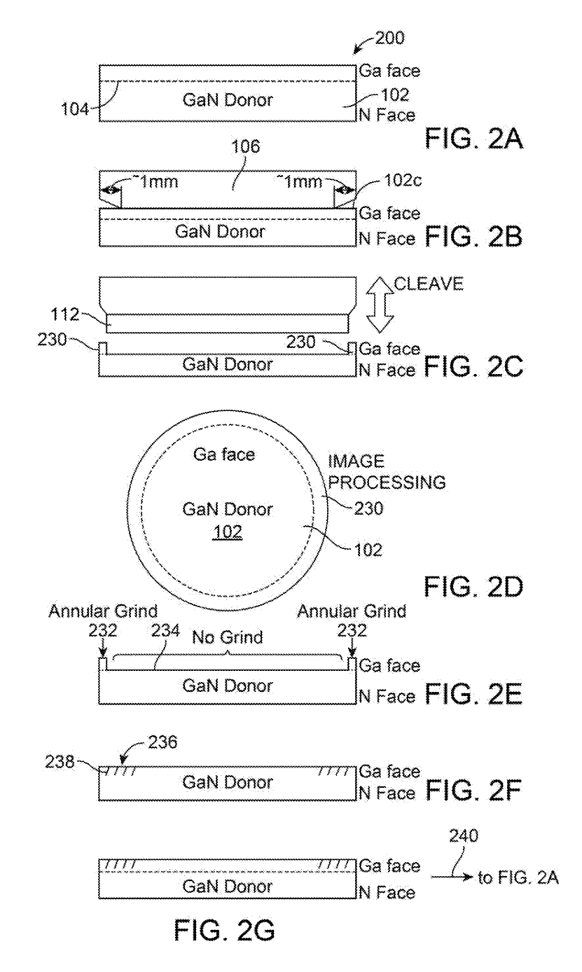

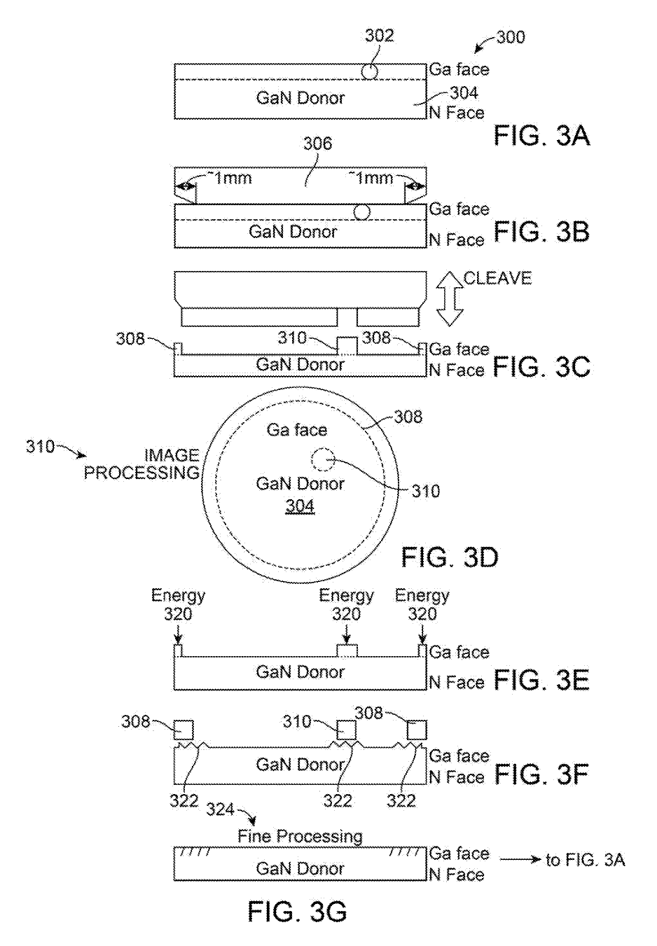

A donor substrate reclamation procedure is shown generally as step 130 in FIG. 1. Various embodiments of reclamation approaches are now described in connection with FIGS. 2A-2G and FIGS. 3A-3G.

In particular, FIGS. 2A-2G show simplified views a GaN substrate undergoing a reclamation procedure 200 according to one embodiment. Here, FIGS. 2A-2D summarize the first three steps of FIG. 1.

Specifically FIG. 2A shows the GaN donor substrate 102, including the cleave region 104 formed, e.g., by ion implantation. Forming a cleave region may depend upon factors such as the target material, the crystal orientation of the target material, the nature of the implanted particle(s), the dose, energy, and temperature of implantation, and the direction of implantation. Such implantation may share one or more characteristics described in detail in connection with the following patent applications, all of which are incorporated by reference in their entireties herein: U.S. patent application Ser. No. 12/789,361; U.S. patent application Ser. No. 12/730,113; U.S. patent application Ser. No. 11/935,197; U.S. patent application Ser. No. 11/936,582; U.S. patent application Ser. No. 12/019,886; U.S. patent application Ser. No. 12/244,687; U.S. patent application Ser. No. 11/685,686; U.S. patent application Ser. No. 11/784,524; U.S. patent application Ser. No. 11/852,088.

FIG. 2B shows the next step, wherein the releasable substrate is bonded to the Ga face of the GaN donor. Here, the releasable layer is omitted for clarity.

FIG. 2B shows that the bound surfaces between the donor substrate and the releasable substrate are not exactly co-extensive. That is, an edge portion 102c (e.g., typically of about 1 mm in width) is not bound to the overlying releasable substrate, owing to a bevel in the side of that releasable substrate. The size of the bevel is substantially exaggerated in FIG. 2B for purposes of illustration.

Accordingly, upon performance of the cleaving step shown in FIG. 2C, the removed releasable substrate carries away with it, the detached thin GaN layer 112 from all but the edge portion of the donor with which the releasable substrate is not in contact. This leaves residual GaN material 230 present at edge portions of the donor substrate. FIG. 2D shows a perspective view of this configuration.

The residual GaN material remains at a height corresponding to the depth of the original cleave region. This creates substantial non-planarity in the donor GaN substrate. Because implant penetration depth is dependent upon the thickness of material, this non-planarity renders the GaN donor substrate unsuited for immediate implant and reuse.

Moreover, it is the Ga face of the GaN donor substrate that exhibits non-planarity. This Ga face exhibits substantial hardness (e.g., ˜430 GPa), rendering it unsuited for removal except under relatively exacting conditions such as grinding.

Accordingly, the specific embodiment of a donor reclamation process shown in the remaining FIGS. 2E-2G, utilizes such a grinding process that is performed exclusively at the edge portions. Specifically, FIG. 2E shows annular grinding 232 directed to the edge portions only, leaving unaffected the central portion 234 resulting from prior removal of the cleaved GaN. This focused, limited grinding may be facilitated by prior image processing (e.g., performed in FIG. 2D) identifying the precise extent and/or nature (e.g., thickness, roughness) of the edge portions.

FIG. 2F shows the result of the localized annular grinding. The raised GaN material at edge portions is removed. However, the resulting edge surfaces may exhibit surface roughness 236 and/or defects 238 extending to a depth into the substrate, that result from the harsh conditions of the annular grinding.

Conventionally, extended and costly surface treatment processes (e.g., polishing) would be employed to remove the surface roughness and/or defects caused by the grinding.

However, in this donor reclamation embodiment, the ongoing presence of surface roughness/defects confined to edge portions of the donor substrate, is acceptable. This is because the subsequent donor reuse 240 involving ion implantation, bonding, and cleaving processes (e.g., in FIGS. 2A-2C) implicates only the central portion of the GaN donor, rather than the edge portions. The edge portion (which now may contain subsurface defects which lower crystal quality and device performance) is limited to non-processed areas of the subsequent transfers. This is an acceptable compromise which help lower complexity and cost of the reclaim process.

It is noted that the process flow shown in FIGS. 2A-2G may be simplified in some respects. In particular, as shown in the process flow 300 of the alternative embodiment of FIG. 3A, under certain conditions gap(s) or void(s) 302 may be present in center portions of the GaN donor substrate 304. These gap(s) or void(s) may affect the nature of the cleaving that occurs in the cleave region.

FIG. 3B shows the bonding of a releasable substrate 306 to the GaN donor including the void.

FIG. 3C shows the resulting cleaving process. As with the embodiment of FIG. 2C, this cleaving results in non-transferred material 308 remaining at the edge portion of the GaN donor.

Moreover, this second embodiment shows that the existence of the void in the central portion also results in residual, non-transferred material 310 remaining in the central portion of the GaN donor following the cleaving.

Unlike residual material GaN material in the edge regions, residual GaN material in the central region is not amenable to removal by local grinding. This is due to the difficulty of precisely positioning a grinder (typically a bulky wheel) at the central substrate location.

Moreover, even if highly precise grinding of central donor substrate portions could be achieved, such grinding would give rise to defects extending to depths in the GaN material. As mentioned above, such defects arising from grinding are amenable to removal only via lengthy/costly post processing steps (e.g., polishing).

Accordingly, FIGS. 3D-3G illustrate an alternative donor substrate reclamation procedure. Specifically, an optional image processing step 310 in FIG. 3D, initially reveals the precise location of residual GaN, both at the edge and in central regions of the donor substrate.

This is followed in FIG. 3E, by the application of energy 320 to at least the locations of the residual GaN material at the edge and center of the donor substrate. The applied energy in this embodiment is laser energy tuned to be preferentially absorbed at the implant peak. Examples of such applied energy are a 532 nm doubled or 355 nm tripled YAG Q-switched laser or a heat lamp. This H-implant absorption effect is described in “Structures and optical properties of implanted GaN epi-layers” by Li & al. Absorption coefficients exceeding 30,000 cm⁻¹ occurs at proton doses of 5-8×10¹⁶ cm⁻² using a 532 nm laser. This strong absorption contrast allows the laser to selectively remove non-cleaved or partially cleaved films at or near the desired cleave plane. Tuning of the beam (e.g., repetition rate, fluence, and pulse-pulse overlap) has been found to effectively remove overlying uncleaved film while reducing or eliminating damage to non-implanted regions.

The nature and/or magnitude of this applied energy may be the same as, or different from, the energy previously used to accomplish cleaving to release the thin layer of GaN material along the cleave region (e.g., as shown in FIG. 3C).

The particular embodiment shown in FIG. 3E indicates the specific application of energy only to (central, edge) locations of the remaining GaN material. Such precise, targeted application of energy may be afforded by an (optional) upstream image processing step.

However, it is noted that alternative embodiments may instead apply the energy 320 in a global (rather than local) manner. For example, energy could be applied globally to the surface of the GaN donor substrate (e.g., by scanned laser or heat lamp), in order to remove the residual GaN material.

Whatever its manner of application, the energy of FIG. 3E is calculated to interact with the cleave region underlying the residual GaN, causing separation from the GaN donor substrate. For example, in certain embodiments optical energy in the form of a laser beam is absorbed at the cleave region and converted to thermal form, resulting in the separation of GaN material at that depth. An energy beam applied from a laser such as a 532 nm (doubled-YAG) or 355 nm (tripled-YAG) laser may be suited for this purpose.

The resulting separation of the residual GaN portions is depicted in FIG. 3F. FIG. 3F also shows the impact on the center and edge regions of the GaN donor substrate, of the separation of residual GaN material by the application of energy. In particular, GaN donor substrate surface locations corresponding to the formerly residual GaN material, may exhibit roughness 322 or other features.

However, unlike the extensive defects arising from the application of harsh grinding techniques, these surface roughness/features 322 do not extend deeply into the GaN donor substrate. Rather, as shown in FIG. 3G they would be expected to impact only about a fraction of a micron of the donor substrate surface. Thus, they may be removed by the application of conditions significantly less severe than those encountered during grinding processes. Examples of such fine processing 324 can include but are not limited to, fine chemical-mechanical polishing, plasma exposure, and/or wet chemical exposure.

Thus, in the manner described, the application of energy to interact with a cleave region, followed by fine processing, may result in reclamation of a donor substrate without the necessity of resorting to harsh grinding conditions. This can substantially improve process throughput and reduce cost.

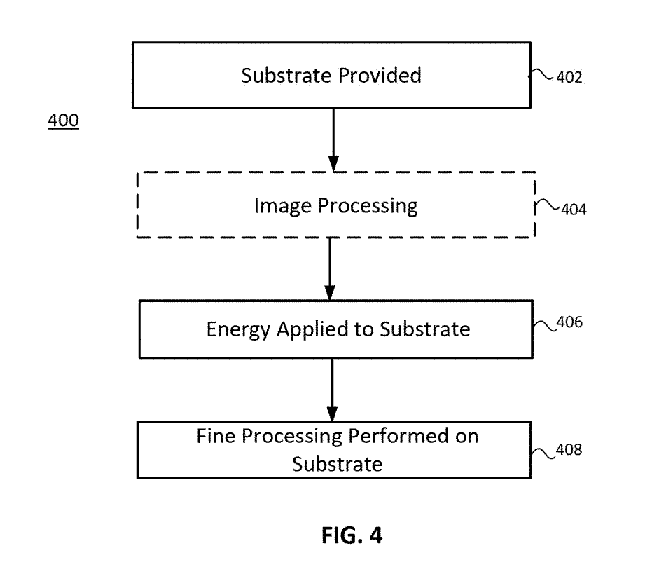

FIG. 4 is a simplified flow diagram illustrating a process 400 of substrate reclamation according to an embodiment. In a first step 402, a substrate comprising a cleave region and residual material is provided.

In an optional second step 404, image processing of the surface of the substrate is performed.

In a third step 406, energy is applied to the substrate in order to separate the residual material from the substrate at the cleave region. In a fourth step 408, the substrate is exposed to one or more fine processing techniques.

It is noted that the substrate reclamation embodiments described in FIGS. 2A-2G and 3A-3G are not mutually exclusive. That is, it is possible to use annular edge grinding techniques to remove residual GaN material at edge regions, and then remove residual GaN material in central regions utilizing the application of energy. Alternatively, these steps may be performed in the reverse order. In such embodiments, image processing taking place between grinding/energy application steps could afford insight into the precise nature (e.g., height, roughness, dimensions) of the remaining GaN material and the conditions for its removal.

While the above description has focused upon the reclamation of a donor substrate comprising GaN material, this is not required. Alternative embodiments could feature donor substrates comprising other Group III/V materials, including but not limited to GaAs. According to certain embodiments a donor such as GaAs may further include a backing substrate such as sapphire.

While the above embodiments have described the reclamation of a donor substrate comprising GaN, this is not required. Alternative embodiments could employ annular grinding and/or energy application in order to remove other types of non-transferred materials. Examples of such non-transferred materials can include but are not limited to high hardness materials such as silicon, silicon carbide, aluminum nitride, sapphire, as well as other materials whose hardness conventionally requires harsh grinding techniques for removal, followed by prolonged polishing to remove damage inflicted by grinding.

And while the above embodiments have described the application of energy to reclaim a donor substrate in which a cleave region is already present (e.g., for layer transfer in central donor substrate portions), this is also not required. Certain embodiments could deliberately create a sub-surface cleave region (e.g., by ion implantation), followed by the application of energy at the cleave region, to prepare a substrate surface that would otherwise require grinding.

That is, implantation followed by energy application according to embodiments, could serve as a substitute for conventional harsh grinding techniques to prepare a high-hardness surface. Such an approach could improve throughput by avoiding not only the grinding step itself, but also extensive/prolonged post-grinding processing to remove grind damage.

Returning to FIG. 1, the particular embodiment illustrated in that figure results in the N face of the GaN layer being bonded to the permanent substrate, with the Ga face of the detached GaN layer exposed for further processing. This is because the Ga face has traditionally proven more amenable to the growth of high quality GaN than the N face.

However, other embodiments are possible. For example some applications (e.g., power electronics) may call for growth of GaN material from the N face, rather than from the Ga face. Incorporated by reference herein for all purposes are the following articles: Xun Li et al., “Properties of GaN layers grown on N-face free-standing GaN substrates”, Journal of Crystal Growth 413, 81-85 (2015); A. R. A. Zauner et al., “Homo-epitaxial growth on the N-face of GaN single crystals: the influence of the misorientation on the surface morphology”, Journal of Crystal Growth 240, 14-21 (2002). Accordingly, template blank structures of some embodiments could feature a GaN layer having an N face that is exposed, rather than a Ga face. Alternatively, an N face donor assembly could be used to fabricate a Ga face final substrate when bonded to a final substrate instead of a releasable transfer substrate as in FIG. 1.

While the above is a full description of the specific embodiments, various modifications, alternative constructions and equivalents may be used. Although the above has been described using a selected sequence of steps, any combination of any elements of steps described as well as others may be used. Additionally, certain steps may be combined and/or eliminated depending upon the embodiment. Furthermore, the particles of hydrogen can be replaced using co-implantation of helium and hydrogen ions or deuterium and hydrogen ions to allow for formation of the cleave region with a modified dose and/or cleaving properties according to alternative embodiments. Still further, the particles can be introduced by a diffusion process rather than an implantation process. Of course there can be other variations, modifications, and alternatives. Therefore, the above description and illustrations should not be taken as limiting the scope of the present invention which is defined by the appended claims.

What is claimed is:

1. A method comprising:
providing a donor substrate comprising a cleave region between residual material and remaining portions of the donor substrate by a cleave region;
applying energy to interact with the cleave region and separate the residual material from the remaining portions of the donor substrate; and
performing fine processing to remove roughness in the donor substrate at the cleave region.

2. A method as in claim 1 wherein the cleave region is formed by implanting particles into the donor substrate.

3. A method as in claim 1 wherein the energy comprises optical energy.

4. A method as in claim 3 wherein the optical energy comprises a laser beam.

5. A method as in claim 4 wherein the laser beam is scanned.

6. A method as in claim 4 wherein the laser beam is targeted at the residual material.

7. A method as in claim 1 wherein the fine processing comprises polishing.

8. A method as in claim 1 wherein the fine processing comprises plasma exposure.

9. A method as in claim 1 wherein the fine processing comprises wet chemical exposure.

10. A method as in claim 1 further comprising performing image processing of the donor substrate to locate the residual material prior to applying energy.

11. A method as in claim 10 wherein the energy is applied based upon results of the image processing.

12. A method as in claim 1 wherein the energy is of a same type as another energy applied to cleave the donor substrate in a central portion in order to transfer a layer to another substrate.

13. A method as in claim 1 wherein the energy is of a different type as another energy applied to cleave the donor substrate in a central portion to transfer a layer to another substrate.

14. A method as in claim 1 wherein the residual material is located in a central portion of the donor substrate.

15. A method as in claim 14 wherein:
the residual material is also located in an edge portion of the donor substrate; and
the method further comprises performing annular grinding at the edge portion.

16. A method as in claim 1 wherein:
the donor substrate comprises GaN; and
the energy is applied to a Ga face of the donor substrate.

17. A method as in claim 1 wherein the energy is applied globally to the donor substrate.

18. A method as in claim 1 wherein:
the donor substrate comprises GaN; and
the energy is applied to a N face of the donor substrate.

19. A method as in claim 1 wherein the energy is applied globally to the donor substrate.

20. A method as in claim 1 wherein the donor substrate comprises GaAs.
